(19) United States
(12) Patent Application Publication
(10) Pub. No.: US 2026/0331611 A1
(43) Pub. Date: Oct. 22, 2026

(54) INFORMATION PROCESSING SYSTEM AND INFORMATION PROCESSING METHOD

(71) Applicant: TOPOLOGIC INC., Tokyo (JP)

(72) Inventor: Arata TAKAHASHI, Tokyo (JP)

(21) Appl. No.: 19/111,187

(22) PCT Filed: Apr. 21, 2023
(86) PCT No.: PCT/JP2023/015905

§ 371 Date: Mar. 12, 2025

(30) Foreign Application Priority Data
Nov. 9, 2022 (JP) 2022-179710

(51) Int. Cl. H01M 10/48

(52) U.S. Cl. CPC H01M 10/486

(57) ABSTRACT

An information processing system is provided. This information processing system comprises a thermoelectric conversion unit and a signal processing unit. The thermoelectric conversion unit is configured so as to generate a thermal gradient by exchanging heat with a device and is configured so as to generate thermoelectric power on the basis of the thermal gradient. The signal processing unit comprises an acquiring unit and a detection unit. The acquiring unit is configured so as to acquire the thermoelectric power. The detection unit is configured so as to detect, on the basis of the thermoelectric power, an abnormal operation of the device accompanied by heat generation.

### CROSS REFERENCE TO RELATED APPLICATIONS

This application is a 371 U.S. National Phase of International Application No. PCT/JP2023/015905, filed on Apr. 21, 2023, which claims priority to Japanese Patent Application No. 2022-179710, filed Nov. 9, 2022. The entire disclosures of the above applications are incorporated herein by reference.

### BACKGROUND

### Technical Field

The present disclosure relates to an information processing system and an information processing method.

### Related Art

JP 2013-118056 A discloses a technique for estimating a temperature corresponding to an internal resistance of a power storage element.

The power storage system described in JP 2013-118056 A includes an power storage element that charges and discharges, a temperature sensor for obtaining a temperature outside the power storage element, and a controller that calculates the temperature at a reference point indicating a temperature corresponding to the internal resistance of the power storage element by using the temperature outside the power storage element and an equation representing the transfer of heat. The controller determines whether or not temperature variations inside the power storage element have been resolved when resuming charging and discharging of the power storage element. When the temperature variations have been resolved, the controller uses a surface temperature of the surface of the power storage element as the temperature of the reference point, and when the temperature variations have not been resolved, the controller calculates the temperature of the reference point.

By the way, when a temperature sensor is used to detect abnormalities of a device or control a device, the temperature change of the temperature sensor itself is necessary. However, since the temperature sensor itself also has a heat capacity, the temperature change of the temperature sensor tends to lag behind the temperature change of the device depending on the heat capacity.

### SUMMARY

According to an aspect of the present disclosure, an information processing system is provided. The information processing system includes a thermoelectric conversion part and a signal processing unit. The thermoelectric conversion part is configured to generate a temperature gradient by heat exchange with a device and to generate a thermoelectromotive force based on the temperature gradient. The signal processing unit includes an acquisition unit and a detection unit. The acquisition unit is configured to acquire the thermoelectromotive force. The detection unit is configured to detect, based on the thermoelectromotive force, abnormal operation of the device accompanied by heat generation.

According to such a configuration, the change in the temperature gradient due to heat generation of the device changes in a short period of time compared to the change in temperature due to heat generation of the device. Thus, it is possible to detect abnormalities of the device or control the device with higher sensitivity than before.

### BRIEF DESCRIPTION OF THE DRAWINGS

FIG. 1 shows an overview of an information processing system 1.

FIG. 2 shows an example of a configuration of a signal processing circuit 35.

FIG. 3 is a perspective view showing an example of structure of power storage units BU.

FIG. 4 is a plan view of one of the power storage units BU shown in FIG. 3 when viewed in a plan view from a first direction D1.

FIG. 5 is a side view of one of the power storage units BU shown in FIG. 3 when viewed in a plan view from a third direction D3.

FIG. 6 is a block diagram showing a hardware configuration of an information processing apparatus 4.

FIG. 7 is a view illustrating an example of functional units included in a processor 43.

FIG. 8 is an activity diagram showing an example of a first information processing flow executed in the information processing system 1.

FIG. 9 is an activity diagram showing an example of a second information processing flow executed in the information processing system 1.

FIG. 10 is an activity diagram showing an example of a third information processing flow executed in the information processing system 1.

FIG. 11 is a cross-sectional view of a power storage device 2 and a thermoelectric conversion part 31 that comes into contact with the power storage device 2, in a plane perpendicular to the third direction D3.

FIG. 12 shows an example of a thermal circuit model M.

FIG. 13 is a cross-sectional view of a power storage device 2, etc., taken along a plane perpendicular to the third direction D3 in a case where a thermoelectric conversion part 31 comes into contact with the power storage device 2 through a temperature adjusting element 6.

FIG. 14 shows another example of a signal processing circuit 35.

FIG. 15 shows an example of a signal processing system 3 that does not include a first heat conduction portion 33.

FIG. 16 shows an example of a mounting aspect of a thermoelectric conversion part 31.

### DETAILED DESCRIPTION

Hereinafter, an embodiment of the present disclosure will be described with reference to drawings. Various features described in the embodiment below can be combined with each other.

A program for realizing a software in the present embodiment may be provided as a non-transitory computer readable storage medium that can be read by a computer, may be provided for download from an external server, or may be provided in such a manner that the program can be activated on an external computer to realize function thereof on a client terminal (so-called cloud computing).

A term “unit” in the present embodiment may include, for example, a combination of a hardware resource implemented as circuits in a broad sense and information processing of software that can be concretely realized by the hardware resource. Furthermore, various kinds of information are described in the present embodiment, and such information may be represented by, for example, physical values of signal values representing voltage and current, high and low signal values as a set of binary bits consisting of 0 or 1, or quantum superposition (so-called qubits), and communication and computation may be executed on a circuit in a broad sense.

The circuit in a broad sense is a circuit realized by properly combining at least a circuit, circuitry, a processor, a memory, and the like. In other words, a circuit includes an application specific integrated circuit (ASIC), a programmable logic device (e.g., simple programmable logic device (SPLD), a complex programmable logic device (CLPD), field programmable gate array (FPGA), and the like.

### 1. Overview of Information Processing System 1

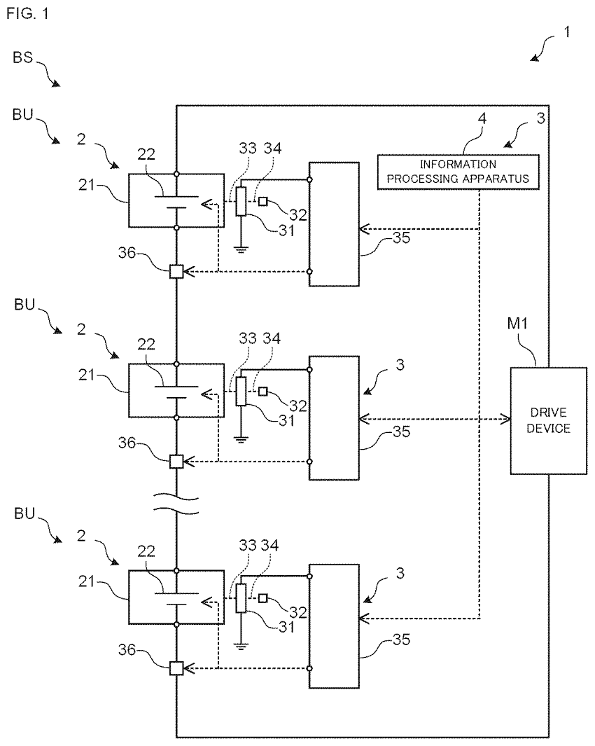

This section describes an overview of an information processing system 1. FIG. 1 shows an overview of the information processing system 1.

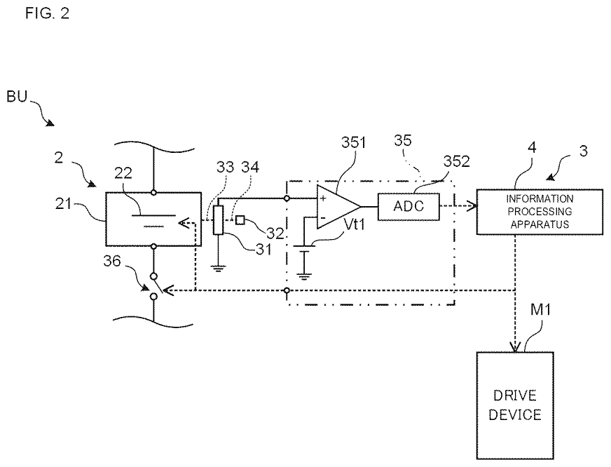

As shown in FIGS. 1 and 2, the information processing system 1 includes a drive device M1 and a power storage system BS. The drive device M1 is configured to be driven by the electric power output from the power storage system BS, and the examples of the drive device M1 include a motor, lighting, a computer, etc. The drive device M1 transmits required power P necessary for its own operation to the outside. The power storage system BS is connected to the drive device M1 through an unshown power converter. The power storage system BS can output electric power in response to the required power P by controlling the power converter. The power storage system BS includes at least one (three or more in the present embodiment) power storage unit BU.

### <Power Storage Unit BU>

Each of the power storage units BU is configured to supply power to the drive device M1 in response to the required power P transmitted from the drive device M1. The power storage units BU are connected in series with each other, and each includes, for example, a power storage device 2 as a device and a signal processing system 3. The power storage units BU may be connected in any manner, and may be connected in parallel.

### <Power Storage Device 2>

The power storage device 2 is configured to charge and discharge power to and from the drive device M1, and includes, for example, a housing 21 and a power storage portion 22 housed inside the housing 21. The housing 21 is configured to conduct heat generated from the power storage portion 22 to at least a part of its surface, and the housing 21 is formed using a thermally conductive material such as metal. A specific aspect of the housing 21 will be described later. The power storage portion 22 is configured to generate an electromotive force V, and examples thereof include a lead-acid battery, a nickel-cadmium storage battery, a lithium-ion storage battery, an air battery, etc. In particular, the lithium-ion storage battery includes iron phosphate-based, iron titanate-based, ternary-based, manganese-based, nickel-based, cobalt-based, NCA (nickel-cobalt-aluminum)-based, and lithium polymer-based batteries. Any one of these batteries, or a combination of two or more of these elements may be used, and there is no particular limitation. The power storage device 2 is configured to generate heat depending on the operating state of the power storage device 2. For example, the power storage device 2 generates heat such that the amount of heat generation increases as the amount of discharge or charge per unit time increases.

### <Signal Processing System 3>

Each of the signal processing systems 3 is configured to process a signal that includes information on the state of the power storage device 2. The signal processing system 3 includes a thermoelectric conversion part 31, a heat bath 32, a first heat conduction portion 33, a second heat conduction portion 34, a signal processing circuit 35, and a switch 36, and at least a part of the signal processing system 3 functions as a signal processing unit.

### <Thermoelectric Conversion Part 31>

The thermoelectric conversion part 31 is configured to generate a temperature gradient J by heat exchange with the power storage device 2 and to generate a thermoelectromotive force E based on the temperature gradient J. In detail, the thermoelectric conversion part 31 is configured to generate a thermoelectromotive force E in response to the temperature gradient J generated in the thermoelectric conversion part 31 by the heat exchange with the power storage device 2. As a result, in the present embodiment, the thermoelectric conversion part 31 can function as a heat flow sensor capable of detecting a heat flow due to heat exchange with the power storage device 2. The thermoelectric conversion part 31 will be described in detail later.

### <Heat Bath 32>

The heat bath 32 is maintained at a predetermined reference temperature Tb. The reference temperature Tb is a temperature that serves as a reference for the temperature gradient J generated in the thermoelectric conversion part 31. The specific configuration of the heat bath 32 is arbitrary, but examples thereof include a housing that houses the power storage unit BU or a housing for the drive device M1, whose temperature is maintained approximately at the outside temperature by heat exchange with the outside air. Also, examples thereof include a member with a sufficiently large heat capacity compared to the housing 21 or the like, such as a metal bath or a salt bath.

### <First Heat Conduction Portion 33>

The first heat conduction portion 33 connects the power storage device 2 (the housing 21 in the present embodiment) and the thermoelectric conversion part 31, and is formed of a thermally conductive material such as a metal. The housing 21 and the thermoelectric conversion part 31 exchange heat with each other through the first heat conduction portion 33. As a result, the temperature gradient J is generated within the thermoelectric conversion part 31 along a direction from the first heat conduction portion 33 toward the thermoelectric conversion part 31. According to such a configuration, heat exchange between the power storage device 2 and the thermoelectric conversion part 31 is conducted through the first heat conduction portion 33, thus making it easier to reduce variations in the thermoelectromotive force E caused by differences in the heat generation positions of the power storage device 2.

### <Second Heat Conduction Portion 34>

The second heat conduction portion 34 is configured to be connected to the heat bath 32, thereby maintaining the temperature of a second region 312 at approximately the reference temperature Tb. According to such a configuration, it becomes easier to more accurately grasp the temperature gradient J of the thermoelectric conversion part 31. Similar to the first heat conduction portion 33, the second heat conduction portion 34 is formed of a thermally conductive material such as a metal. The thermoelectric conversion part 31 and the heat bath 32 exchange heat with each other through the second heat conduction portion 34. The system of the present embodiment is configured to allow heat exchange between the housing 21 and the thermoelectric conversion part 31 to occur, and to allow heat exchange between the thermoelectric conversion part 31 and the heat bath 32 to occur, respectively. According to such a configuration, the operating temperature of the thermoelectric conversion part 31 is stabilized, thereby improving the detection accuracy of the heat generation state of the power storage device 2. The heat bath 32 is an example of a temperature adjusting part that can adjust the temperature of the second heat conduction portion 34.

### <Signal Processing Circuit 35>

The signal processing circuit 35 is configured to acquire the thermoelectromotive force E generated from the thermoelectric conversion part 31 and to control the power storage device 2, etc. in response to the thermoelectromotive force E. The thermoelectromotive force E is an example of a first signal due to the thermoelectromotive force E.

Here, an example of a configuration of the signal processing circuit 35 is described. FIG. 2 shows an example of a configuration of the signal processing circuit 35. As shown in FIG. 2, the signal processing circuit 35 includes a comparing unit 351 and an AC-DC converter 352.

### <Comparing Unit 351>

The comparing unit 351 is configured to compare the thermoelectromotive force E of the thermoelectric conversion part 31 with a threshold voltage Vt1 as a predetermined reference value. The comparing unit 351 of the present embodiment is configured by an operational amplifier, the inverting input terminal thereof is connected to a reference power supply that outputs a threshold voltage Vt1, and the non-inverting input terminal is connected to the thermoelectric conversion part 31. Thus, when the thermoelectromotive force E output from the thermoelectric conversion part 31 exceeds the threshold voltage Vt1, the comparing unit 351 outputs an analog voltage signal corresponding to the difference between the thermoelectromotive force E and the threshold voltage Vt1.

### <AC-DC Converter 352>

The AC-DC converter 352 is connected to an output terminal of the comparing unit 351. The AC-DC converter 352 is configured to convert an analog voltage signal output from the comparing unit 351 into a digital signal. The digital signal is output to, for example, an information processing apparatus 4.

### <Switch 36>

The switch 36 is configured to allow charging and discharging of the power storage device 2 when turned on, and to restrict, and more specifically, stop charging and discharging of the power storage device 2 when turned off. The specific aspect of the switch 36 is arbitrary. For example, in a case where the switch 36 is a single-pole single-throw type, the charge and discharge of all the power storage devices 2 are restricted when the switch 36 is turned off. Furthermore, in a case where the switch 36 is a single-pole double-throw type, when the switch 36 is turned off, the circuit is connected to a redundant circuit that bypasses the power storage device 2 corresponding to the switch 36, thereby restricting the independent charge and discharge of the corresponding power storage device 2.

### <Information Processing Apparatus 4>

In the present embodiment, one of the signal processing systems 3 further includes an information processing apparatus 4. The information processing apparatus 4 is configured to cooperatively control each of the signal processing systems 3, and functions as, for example, a battery management system (BMS). The information processing apparatus 4 of the present embodiment is configured to control the drive device M1, as a second device that is a device other than the power storage device 2.

### 2. An Example of the Structure of the Power Storage Unit BU

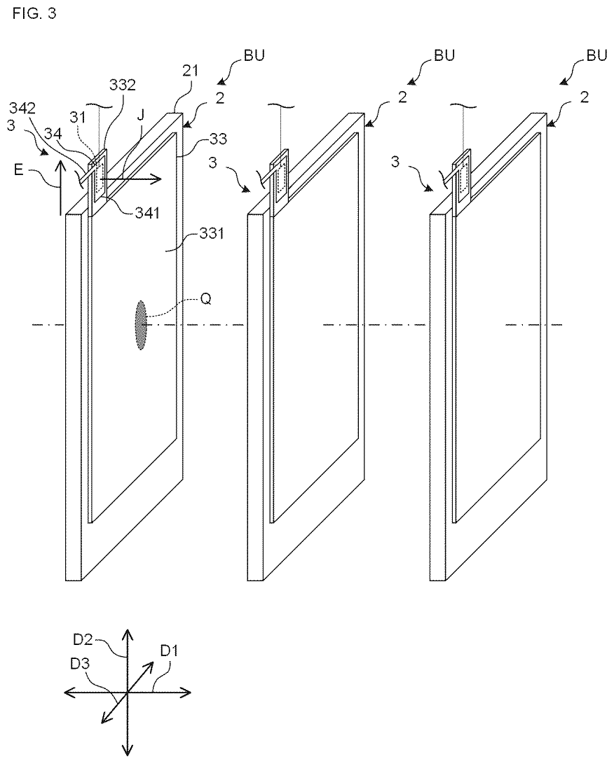

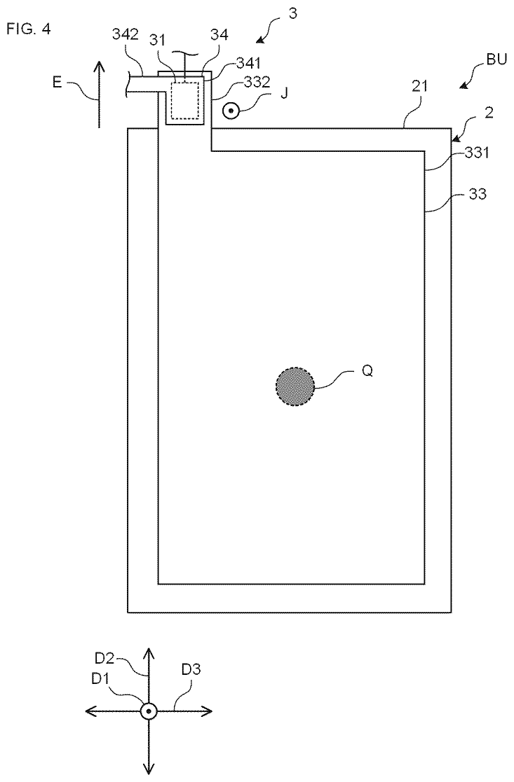

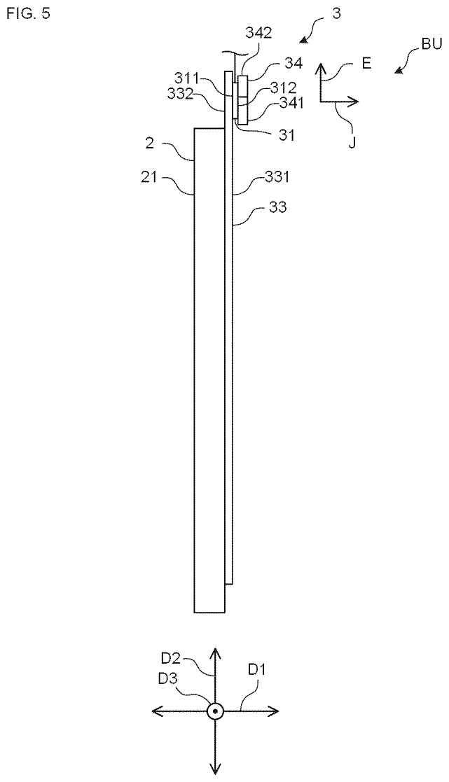

This section describes an example of the structure of the power storage unit BU described above. FIG. 3 is a perspective view showing an example of structure of the power storage units BU. FIG. 4 is a plan view of one of the power storage units BU shown in FIG. 3 when viewed in a plan view from a first direction D1. FIG. 5 is a side view of one of the power storage units BU shown in FIG. 3 when viewed in a plan view from a third direction D3.

As shown in FIG. 3, each of the power storage units BU is configured in a flat plate shape within a plane whose normal extends in the first direction D1, and the power storage units BU are stacked with each other in the first direction D1 to form a single assembly. The first direction D1 may also be referred to as a stacking direction. For convenience of explanation, various wirings extending from the power storage unit BU are not shown. For convenience of explanation, the two directions perpendicular to the first direction D1 are referred to as a second direction D2 and a third direction D3, respectively. The second direction D2 and the third direction D3 are perpendicular to each other.

As shown in FIGS. 3 to 5, the housing 21 of the power storage device 2 is formed to be a flat rectangular parallelepiped whose normal extends in the first direction D1, and its thickness direction is parallel to the first direction D1. The long sides of the housing 21 extend along the second direction D2, and the short sides of the housing 21 extend along the third direction D3. In the present embodiment, the second direction D2 can also be referred to as a long side direction, and the third direction D3 can also be referred to as a short side direction. The power storage device 2 generates heat due to operations such as charging and discharging, or due to abnormalities such as a failure of the power storage portion 22, and a heat source Q may be generated inside the housing 21. In the present embodiment, a case where a heat source Q is generated in the center of the power storage device 2 will be described. The position of the heat source Q is not limited to the center and may be any position, for example, on the surface or inside of the power storage device 2, or at an end of the power storage device.

The first heat conduction portion 33 is formed in a flat plate shape with a normal extending in the first direction D1. The first heat conduction portion 33 includes a main surface portion 331 and a protruding portion 332.

### <Main Surface Portion 331>

The main surface portion 331 is formed in a rectangular flat plate shape, similar to the housing 21, and the thickness direction thereof is parallel to the first direction D1. The long side direction of the main surface portion 331 extends along the second direction D2, and the short side direction of the main surface portion 331 extends along the third direction D3. The main surface portion 331 comes into contact with the housing 21 in the first direction D1, so that the heat generated from the heat source Q is transferred to the surface of the housing 21 through the housing 21 and is transferred from the surface of the housing 21 to the main surface portion 331.

When one of the power storage units BU is viewed in a plan view from the first direction D1, the outer edge of the main surface portion 331 in the plane perpendicular to the first direction D1 is formed so as to be included inside the outer edge of the main surface portion 331 in the plane perpendicular to the first direction D1.

### <Protruding Portion 332>

As shown in FIG. 4, the protruding portion 332 is configured to protrude from the power storage device 2 when the power storage device 2 is viewed in a plan view from the predetermined first direction D1. That is, the protruding portion 332 extends from a part of the outer edge of the main surface portion 331 in the second direction D2. Thus, even when a plurality of power storage units BUs is stacked, each of the protruding portions 332 is configured not to be held by the housings 21. According to such a configuration, the thermoelectromotive force E of the thermoelectric conversion part 31 can be measured more easily, and thus the degree of freedom in arranging the power storage device 2 and the like can be improved. The protruding portion 332 has a square flat plate shape whose thickness direction extends along the first direction D1, and is integrally formed so as to be flush with the main surface portion 331. The shape of the protruding portion 332 is arbitrary and is not limited thereto. In addition, the protruding portions 332 of the different power storage units BU may be configured not to overlap with each other when the power storage device 2 is viewed in a plan view from the first direction D1. According to such a configuration, thermal convection near the protruding portion 332 can be promoted by ensuring a space near the protruding portion 332 in the first direction D1. On the other hand, the protruding portions 332 of the different power storage units BU may be configured to overlap with each other when the power storage device 2 is viewed in a plan view from the first direction D1. According to such a configuration, an assembly configured by a plurality of power storage units BU can be made more compact.

### <Thermoelectric Conversion Part 31>

The thermoelectric conversion part 31 is configured to generate a thermoelectromotive force E including a component generated in a direction different from the temperature gradient J. According to such a configuration, it becomes easier to measure the thermoelectromotive force E from a direction different from the temperature gradient J, thereby reducing the wirings, etc. between the power storage device 2 and the thermoelectric conversion part 31. Thus, the decrease in sensitivity to the temperature gradient J can be suppressed. In the present embodiment, the temperature gradient J occurs along the first direction D1, and the thermoelectromotive force E includes a component that occurs in the second direction D2 perpendicular to the first direction D1. The thermoelectric conversion part 31 is configured so that the thermoelectromotive force E changes in response to temperature changes of the surface of the power storage device 2 (for example, an area of the surface of the housing 21, which comes into contact with the thermoelectric conversion part 31) due to heat generation. The thermoelectric mechanism of such a thermoelectromotive force E is arbitrary, but can be realized by, for example, the anomalous Nernst effect. The thermoelectric conversion part 31 generates a thermoelectromotive force E in a direction perpendicular to both the temperature gradient J and the direction characterizing the magnetic structure, due to the anomalous Nernst effect, with a magnetic structure characterized in a direction perpendicular to the temperature gradient J. In other words, the anomalous Nernst effect is expressed by the quantity that depends on a physical variable corresponding to a magnetic field among the off-diagonal components of the thermoelectric tensor of the thermoelectric conversion part 31. The thermoelectromotive force E is antisymmetric with respect to the magnetic field, symmetric with respect to the in-plane component perpendicular to the first direction D1 of the temperature gradient J, and antisymmetric with respect to the vertical component parallel to the first direction D1.

Examples of compositions capable of exhibiting such an anomalous Nernst effect include Mn₃Sn, Mn₃Ge, Mn₃Ga, Co₂MnGa, Fe₃Al, Fe₃Ga, Fe₃Sn₂, FeGa, L1_0 type FePt, L1_0 type FePd, L1_0 type MnGa, D0_22 type Mn2Ga, SmCo5, Nd2Ir2O7 or alloys, element substitutes, or mixtures thereof, but are not limited to those listed here and are arbitrary. The anomalous Nernst coefficient may be increased by adding any substance such as MgO, to these compositions. Thus, the thermoelectric conversion part 31 is not limited to being composed solely of the above-mentioned compositions. The mechanism by which the anomalous Nernst effect is exhibited is arbitrary, but examples include one resulting from an antiferromagnetic magnetic structure with a non-collinear spin configuration, or one resulting from a unique band structure called a Weyl point or nodal web. In these structures, the quantity that represents the geometrical features (for example, the Chern number) becomes finite due to the symmetry of the band structure, etc., and this is presumably one of the factors that causes the anomalous Nernst effect to be exhibited. For example, it is thought that the anomalous Nernst effect is exhibited when the wave function of the electrons that constitute the system acquires a Berry phase corresponding to the feature value, and the Berry phase functions as a virtual magnetic field acting on the electrons. The geometric feature value is calculated from, for example, a band structure obtained by band calculation from the microscopic structure (including the crystal structure and magnetic structure) of a substance. In this case, the Nernst coefficient tends to be larger than those of other expression mechanisms, which facilitates more accurate measurements and makes it easier to miniaturize the element. Furthermore, the materials constituting the thermoelectric conversion part 31 may be realized as a polycrystalline body or as a single-crystal body of these materials. The crystallographic domains of the single-crystal body may be sufficiently uniform to the extent that asymmetrical physical properties due to a reduction in symmetry associated with the emergence of magnetic order, can be observed. The thickness of the thermoelectric conversion part 31 in the first direction D1, or more specifically, the thickness of the structure that exhibits the anomalous Nernst effect included in the thermoelectric conversion part 31, is arbitrary, but specifically may be, for example, 5, 6, 7, 8, 9, 10, 20, 30, 40, 50, 60, 70, 80, 90, 100, 200, 300, 400, 500, 600, 700, 800, 900 nm, and may be within a range between any two of the numerical values exemplified here. It may also be outside these ranges. The method of implementing the thermoelectric material that exhibits the anomalous Nernst effect or the like as the thermoelectric conversion part 31 is arbitrary. Any method may be employed, including physical vapor deposition methods such as sputtering and ion plating, plating methods, chemical vapor deposition, molecular beam epitaxial growth (MBE), and various printing methods such as inkjet printing using droplets in which the above-mentioned compounds are dissolved.

The thermoelectric conversion part 31 of the present embodiment utilize such an anomalous Nernst effect, allowing it to be formed thinner and with a smaller volume compared to a thermoelectric conversion part that utilizes the Seebeck effect, while maintaining its sensitivity to heat flow (i.e., the magnitude of the thermoelectromotive force E relative to the temperature gradient J per unit area). For convenience of explanation, a thermoelectric conversion part that utilizes the Seebeck effect may be hereinafter referred to as a Seebeck element. In addition, the thermoelectric conversion part 31 of the present embodiment has a smaller volume than a Seebeck element, and thus the overall heat capacity can be reduced. Therefore, the thermoelectric conversion part 31 of the present embodiment can respond to temperature changes of a measurement target such as the power storage device 2 in a relatively short time compared to a Seebeck element, and can achieve high time resolution and high sensitivity. In some cases, it is possible to achieve both of these characteristics that have conventionally tended to be a trade-off. According to such a configuration, it is possible to detect the dynamics of instantaneous changes in heat, such as the occurrence of abnormal heat generation, which could not be detected by conventional thermometers or heat flow sensors.

The thermoelectric conversion part 31 includes a first region 311 and a second region 312, and the first region 311 of the thermoelectric conversion part 31 is connected to the protruding portion 332. As a result, heat from the heat source Q of the power storage device 2 is transferred through the first heat conduction portion 33 to the main surface portion 331 and the protruding portion 332 in that order, and then transferred from the protruding portion 332 to the thermoelectric conversion part 31 through the first region 311. Heat exchange between the thermoelectric conversion part 31 and the power storage device 2 is performed through such a heat conduction path. The second region 312 is positioned in the direction of the temperature gradient J (i.e., the first direction D1) from the first region 311. The second region 312 can be regarded as a region positioned opposite the first region 311 in the thickness direction of the thermoelectric conversion part 31. The second region 312 has a front-back relationship with the first region 311.

### <Second Heat Conduction Portion 34>

The second heat conduction portion 34 includes a contact portion 341 and a heat transporting portion 342, and the contact portion 341 of the second heat conduction portion 34 is connected to the second region 312. The contact portion 341 is arranged so as to cover the second region 312 of the thermoelectric conversion part 31 when the power storage device 2 is viewed in a plan view from the first direction D1. This allows the temperature of the second region 312 of the thermoelectric conversion part 31 to be suppressed from varying depending on the position. Similar to the thermoelectric conversion part 31, the contact portion 341 of the present embodiment is formed in a rectangular flat plate shape with a thickness direction thereof extending along the first direction D1.

The heat transporting portion 342 is connected to the outer edge of the contact portion 341, extends from the outer edge in the second direction D2, and is connected to the heat bath 32 (not shown). The heat bath 32 exchanges heat with the second region 312 of the thermoelectric conversion part 31 sequentially through the heat transporting portion 342 and the contact portion 341. This makes it easier to maintain the surface temperature of the second region 312 of the thermoelectric conversion part 31 at the reference temperature Tb of the heat bath 32. On the other hand, the surface temperature of the first region 311 of the thermoelectric conversion part 31 increases due to the heat generated from the heat source Q in the housing 21. As a result, in the thermoelectric conversion part 31, a temperature gradient J occurs along the first direction D1 due to the difference between the surface temperature of the first region 311 and the surface temperature of the second region 312. As described above, the surface temperature of the second region 312 is easily maintained at the reference temperature Tb. Thus, it is possible to grasp the temperature gradient J that occurs in the thermoelectric conversion part 31 depending on the temperature of the second heat conduction portion 34. This can increase the information obtained from the thermoelectromotive force E. Thus, a wider variety of heat-related processing can be performed.

In the present embodiment, the surface of the contact portion 341, which is positioned opposite to the surface that comes into contact with the second region 312 in the first direction D1, is exposed to air. Thus, if the temperature of the thermoelectric conversion part 31 becomes excessively high, the heat accumulated in the thermoelectric conversion part 31 is released into the air through the contact portion 341. Accordingly, the second heat conduction portion 34 (particularly, the contact portion 341) functions as a heat dissipation portion capable of dissipating at least a portion of the heat flowing into the thermoelectric conversion part 31 through heat exchange. In other words, the second heat conduction portion 34 includes such a heat dissipation portion. According to such a configuration, heat generated by the power storage device 2 can be released from the heat dissipation portion, so that an excessive increase in temperature of the thermoelectric conversion part 31 can be suppressed.

### 3. Hardware Configuration of Information Processing Apparatus 4

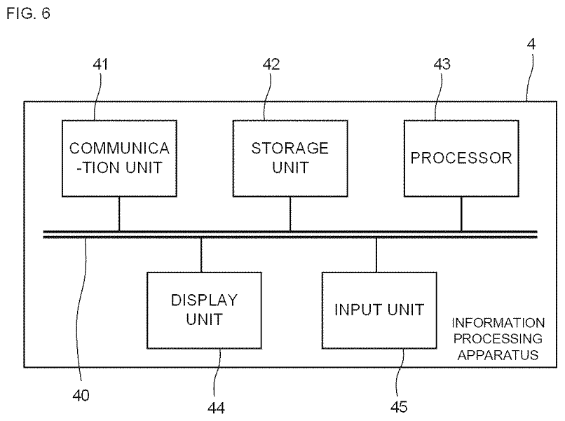

This section describes an example of a hardware configuration of the above-mentioned information processing apparatus 4. FIG. 6 is a block diagram showing a hardware configuration of the information processing apparatus 4. The information processing apparatus 4 includes a communication bus 40, a communication unit 41, a storage unit 42, a processor 43 as a controller, a display unit 44, and an input unit 45. These components are electrically connected inside the information processing apparatus 4 via the communication bus 40.

### <Communication Unit 41>

The communication unit 41 may be preferably wired communication means such as USB, IEEE1394, Thunderbolt (registered trademark), wired LAN network communication, and the like, but may include wireless LAN network communication, mobile communication such as 3G/LTE/5G, Bluetooth (registered trademark) communication, and the like as needed. In other words, more preferably, the communication unit 41 is implemented as a set of these communication means. That is, the information processing apparatus 4 may communicate various information from outside via the communication unit 41 and a network.

### <Storage Unit 42>

The storage unit 42 is configured to store various information as defined by the above description. For example, the storage unit 42 may be implemented as a storage device such as a solid state drive (SSD) that stores various programs, etc. related to the information processing apparatus 4, which are executed by the processor 43, or as a memory such as a random access memory (RAM) that stores temporarily necessary information (arguments, arrays, etc.) for program calculations. The storage unit 42 stores various programs, variables, etc. related to the information processing apparatus 4 that are executed by the processor 43.

### <Processor 43>

The processor 43 processes and controls overall operation pertaining to the information processing apparatus 4. The processor 23 is, for example, an unshown central processing unit (CPU). The processor 43 reads out a predetermined program stored in the storage unit 42 so as to realize various functions related to the information processing apparatus 4. That is, the information processing by software stored in the storage unit 42 is specifically realized by the processor 43 as an example of hardware, and can be executed as each functional unit included in the processor 43. They will be described in more detail in the next section. The processor 43 is not limited to be a single processor, but may be implemented so as to include a plurality of the processors 43 for each function. Moreover, a combination thereof may be applied.

### <Display Unit 44>

The display unit 44 may be included in the housing of the information processing apparatus 4, or the display unit 44 may be externally mounted. The display unit 44 displays a graphical user interface (GUI) screen that can be operated by the user. This should be implemented, for example, by using different display devices such as a CRT display, a liquid crystal display, an organic EL display, and a plasma display, depending on the type of the information processing apparatus 4.

### <Input Unit 45>

The input unit 45 may be included in the housing of the information processing apparatus 4, or the input unit 45 may be externally mounted. For example, the input unit 45 may be integrated with the display unit 44 and implemented as a touch panel. With a touch panel, the user can input taps, swipes, etc. Of course, a switch button, mouse, QWERTY keyboard, etc. may be employed instead of a touch panel. In other words, the input unit 45 receives operation inputs made by the user. The input is transferred as an instruction signal to the processor 43 via the communication bus 40, and the processor 43 can execute predetermined control or computation as necessary.

### 4. Functional Configuration of Information Processing Apparatus 4

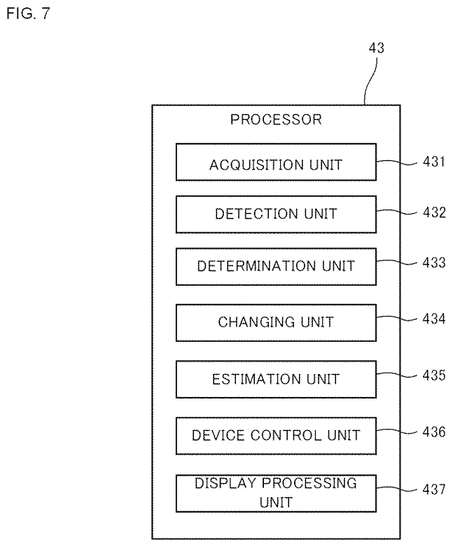

In this section, an example of the functional configuration of the processor 43 described above will be shown. FIG. 7 is a view illustrating an example of functional units included in the processor 43. The processor 43 includes an acquisition unit 431, a detection unit 432, a determination unit 433, a changing unit 434, an estimation unit 435, a device control unit 436, and a display processing unit 437.

The acquisition unit 431 is configured to acquire information from the power storage device 2 or other devices and execute an acquisition step. The acquisition unit 431 is configured to acquire various information by: reading out the various information stored in a storage area, which is at least a part of the storage unit 42; and writing the readout information into a working area, which is at least a part of the storage unit 42. The storage area is, for example, an area in the storage unit 42, which is implemented as a storage device such as an SSD. The working area is, for example, an area which is implemented as a memory such as RAM.

The detection unit 432 is configured to detect an abnormality in a device such as the power storage device 2 based on the acquired various information, etc., and execute a detection step.

The determination unit 433 is configured to determine the operating state of the device such as the power storage device 2 based on the acquired various information, etc., and execute a determination step.

The changing unit 434 is configured to change the operation of the device such as the power storage device 2 based on the acquired various information, etc., and execute a changing step.

The estimation unit 435 is configured to estimate various information such as the state of the device such as the power storage device 2 and the position of the heat source Q generated by the operation of the device, based on the acquired various information, etc., and to execute a first estimation step and a second estimation step.

The device control unit 436 is configured to control the operation of the device such as the power storage device 2 and the drive device M1, based on various information.

The display processing unit 437 is configured to display various information. The information can be presented to the user via the display unit 44 or other device. In such a case, for example, the display processing unit 437 controls the display unit 44 to display visual information such as screens, images including still or moving images, icons, messages and the like. The display processing unit 437 may generate only rendering information for displaying the visual information on the information processing apparatus 4 or a user terminal which is not shown. The display processing unit 437 may present the output information to the user not via any other device.

### 5. Information Processing

This section describes the information processing executed in the information processing system 1 described above. It should be noted that the information processing may include any exception processing not shown. The exception processing includes interruption of the information processing or omission of each process. Selection or input performed in the information processing may be based on operations by the user, or may be automatic not by the user's operations.

### 5.1. First Information Processing

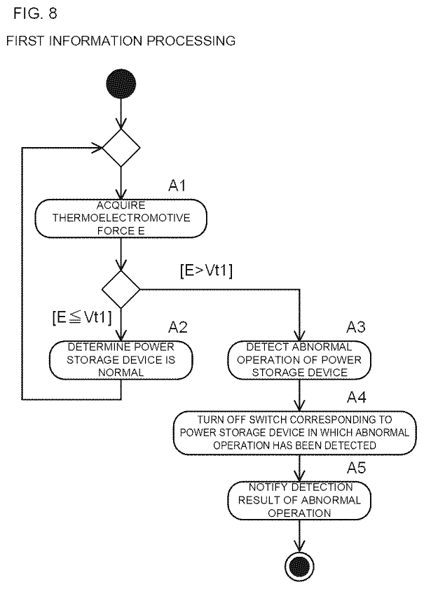

This section describes first information processing, which is an example of information processing executed by the information processing system 1 described above. FIG. 8 is an activity diagram showing an example of the first information processing flow executed in the information processing system 1. The information processing system 1 can detect abnormal operation of the power storage device 2 by executing the first information processing.

### [Activity A1]

First, in Activity A1, the acquisition unit 431 acquires a thermoelectromotive force E. In the present embodiment, the acquisition unit 431 acquires an output signal output from the comparing unit 351 based on the thermoelectromotive force E. In other words, the acquisition unit 431 indirectly acquires the thermoelectromotive force E. Thereafter, the determination unit 433 determines whether or not the acquired thermoelectromotive force E is less than or equal to the threshold voltage Vt1. In the present embodiment, since the comparing unit 351 outputs an output signal when the thermoelectromotive force E is greater than the threshold voltage Vt1, the determination unit 433 may make the determination based on whether or not the acquisition unit 431 has acquired the output signal. In the present embodiment, the determination is made for each of a plurality of power storage devices 2, but the present disclosure is not limited thereto. The determination may be made collectively for at least some of the power storage devices 2.

### [Activity A2]

In the case where it is determined that the thermoelectromotive force E is equal to or less than the threshold voltage Vt1, the process proceeds to Activity A2, where the determination unit 433 determines that the power storage device 2 is normal, and allows the power storage device 2 to continue operating. After that, the process returns to Activity A1, and the acquisition and determination of the thermoelectromotive force E are repeated.

### [Activity A3]

On the other hand, in the case where it is determined that the thermoelectromotive force E is greater than the threshold voltage Vt1, the process proceeds to Activity A3, and the detection unit 432 detects, based on the thermoelectromotive force E, abnormal operation of the power storage device 2 accompanied by heat generation. According to such a configuration, the change in the temperature gradient J due to heat generation of the power storage device 2 changes in a short time compared to a temperature change due to heat generation of the power storage device 2. As a result, abnormal heat generation in the power storage device 2 can be detected with higher sensitivity compared with the conventional manner.

### [Activity A4]

Next, the process proceeds to Activity A4, and the processor 43 turns off the switch 36 corresponding to the power storage device 2 in which the abnormal operation has been detected. This restricts the charging and discharging of at least the power storage device 2 that has been turned off. Detecting an operational abnormality also means determining the operating state of the power storage device 2. Thus, the determination unit determines the operating state of the power storage device 2 in response to the thermoelectromotive force E. According to such a configuration, the change in the temperature gradient J due to heat generation of the power storage device 2 changes in a short time compared to the temperature change due to heat generation of the power storage device 2. As a result, the operating state of the power storage device 2 can be distinguished with higher sensitivity compared with the conventional manner.

### [Activity A5]

Next, the process proceeds to Activity A5, and the display processing unit 437 notifies the user of a detection result of the abnormal operation. The display processing unit 437 visually notifies the user, for example, via the display unit 44, of information related to the power storage device 2 in which abnormal operation has been detected. The information related to the power storage device 2 includes, for example, details of the abnormal operation of the power storage device 2. The notification method is not limited to this and may be any method, such as using sound, light, or the like. Thereafter, the first information processing ends.

To summarize the above, the information processing system 1 includes the thermoelectric conversion part 31, the signal processing circuit 35 as a signal processing unit, and the information processing apparatus 4. The thermoelectric conversion part 31 is configured to generate a temperature gradient J by heat exchange with the power storage device 2 as a device, and to generate a thermoelectromotive force E based on the temperature gradient J. The processor 43 of the information processing apparatus 4 included in the signal processing unit includes the acquisition unit 431 and the detection unit 432. The acquisition unit 431 is configured to acquire a thermoelectromotive force E. The detection unit 432 is configured to detect, based on the thermoelectromotive force E, abnormal operation of the power storage device 2 accompanied by heat generation.

According to such a configuration, the change in the temperature gradient J due to heat generation of the device changes in a short time compared to the temperature change due to heat generation of the device. As a result, the abnormal heat generation of the device can be detected with higher sensitivity compared with the conventional manner.

### 5.2. Second Information Processing

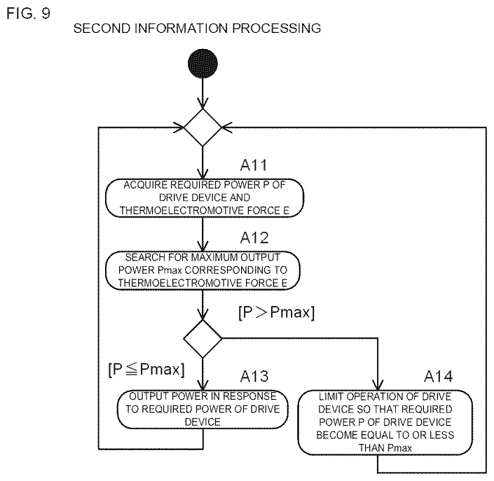

This section describes second information processing, which is an example of information processing executed by the information processing system 1 described above. FIG. 9 is an activity diagram showing an example of the second information processing flow executed in the information processing system 1. The information processing system 1 can control the operation of the power storage device 2 or the like based on the acquired thermoelectromotive force E by executing the second information processing. Controlling the power storage device 2 is not limited to controlling the power storage device 2 by directly transmitting a signal to the power storage device 2, but also includes indirectly controlling the power storage device 2 by transmitting a signal to a device different from the power storage device 2 (e.g., a power converter or the drive device M1) and controlling the operation of that device.

### [Activity A11]

First, in Activity A11, the acquisition unit 431 acquires required power P of the drive device M1 and a thermoelectromotive force E. The thermoelectromotive force E may be acquired in any manner. In the case where the signal processing circuit 35 includes a voltage measuring unit capable of measuring a thermoelectromotive force E, the acquisition unit 431 may acquire a value of the thermoelectromotive force E from the voltage measuring unit. In the case where the signal processing circuit 35 includes a plurality of comparing units 351 in such a manner that the thermoelectromotive force E can be compared with a plurality of threshold voltages, the acquisition unit 431 may acquire comparison results between the thermoelectromotive force E and each of the plurality of threshold voltages.

### [Activity A12]

Next, the process proceeds to Activity A12, and the processor 43 searches for the maximum output power Pmax corresponding to the thermoelectromotive force E based on the predetermined reference information IFO. The reference information IFO is information that specifies the correspondence relationship between the thermoelectromotive force E and the maximum output power Pmax, and is stored in the storage unit 42 or the like. The thermoelectromotive force E is information that represents a heat flow accompanied by the temperature gradient J, and thus the thermoelectromotive force E is information that suggests the temperature of the power storage device 2, or more specifically, the temporal change in temperature. Thus, the reference information IFO is information indicating the temperature of the power storage device 2 and the maximum output power Pmax that the power storage device 2 can output at that temperature. The reference information IFO can be generated based on, for example, the results of a test performed in advance or the results of a predetermined simulation, and the format of the reference information IFO can be any format, such as a function, a look-up table, or a trained model.

Thereafter, the determination unit 433 compares the obtained required power P with the maximum output power Pmax obtained by the search and determines their magnitude relationship. In the present embodiment, the comparing unit 351 outputs the comparison result of the thermoelectromotive force E as the first electric signal, and the changing unit 434 changes the operation of the power storage device 2 based on the comparison result of the thermoelectromotive force E. According to such a configuration, the thermoelectromotive force E generated from the thermoelectric conversion part 31 can be grasped as a difference from the reference value. Thus, it becomes easier to stably change the operation of the power storage device 2 by the electric signal output from the thermoelectric conversion part 31. The changing unit 434 changes, for example, whether the next activity to be processed is Activity A13 or Activity A14, based on the comparison result of the thermoelectromotive force E.

### [Activity A13]

When the required power P is equal to or less than the maximum output power Pmax, the process proceeds to Activity A13, and the device control unit 436 causes the power storage device 2 to output electric power in response to the required power P of the drive device M1. The output power of the power storage device 2 is controlled, for example, through a power converter (not shown). The process then returns to Activity A11.

### [Activity A14]

On the other hand, when the required power P is greater than the maximum output power Pmax, the process proceeds to Activity A14, and the device control unit 436 limits the drive device M1 so that the required power P of the drive device M1 becomes equal to or less than the maximum output power Pmax. Then, the device control unit 436 causes the power storage device 2 to output power in response to the limited required power P. This allows the power storage device 2 to output power suited to its temperature condition, thereby making it possible to suppress the progression of deterioration of the power storage device 2. In this manner, the information processing system 1 searches for the maximum output power Pmax based on the thermoelectromotive force E and controls the output power of the power storage device 2 so as not to exceed the maximum output power Pmax.

To summarize the above, the information processing system 1 includes the thermoelectric conversion part 31, the signal processing circuit 35 as a signal processing unit, and the information processing apparatus 4. The thermoelectric conversion part 31 is configured to generate a thermoelectromotive force E in response to the temperature gradient J generated in the thermoelectric conversion part 31 by the heat exchange with the power storage device 2 as a device. The processor 43 of the information processing apparatus 4 included in the signal processing unit includes the acquisition unit 431 and the device control unit 436. The acquisition unit 431 is configured to acquire a thermoelectromotive force E. The device control unit 436 is configured to control the operation of the device based on the acquired thermoelectromotive force E.

According to such a configuration, the change in the temperature gradient J due to heat generation of the device changes in a short time compared to the temperature change due to heat generation of the device. As a result, the device can be controlled with a faster response speed compared with the conventional manner.

### 5.2. Third Information Processing

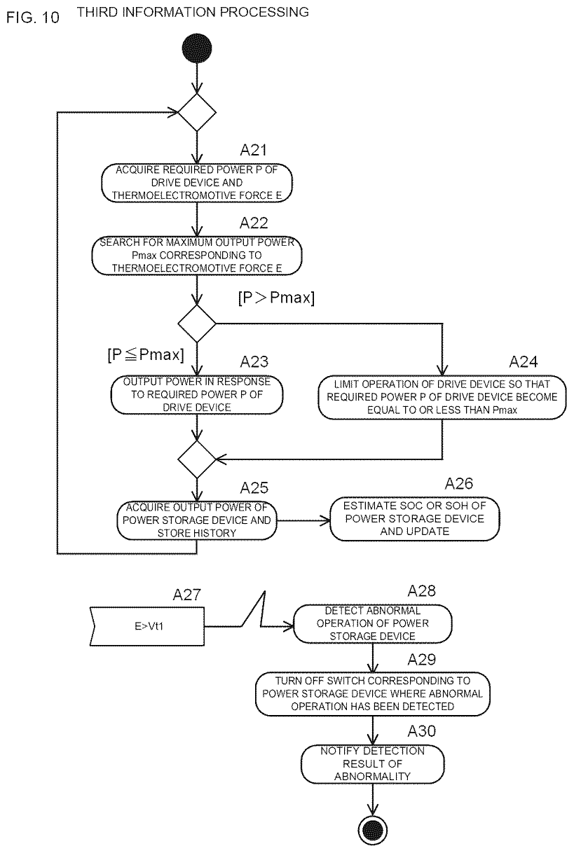

This section describes the third information processing, which is an example of information processing executed by the information processing system 1 described above. FIG. 10 is an activity diagram showing an example of the third information processing flow executed in the information processing system 1. The information processing system 1 can further estimate the state of charge or the state of health of the power storage device 2 by executing the third information processing.

### [Activity A21]

First, in Activity A21, the acquisition unit 431 acquires the required power P of the drive device M1 and a thermoelectromotive force E. The details of the process are the same as those of Activity A11.

### [Activity A22]

Next, the process proceeds to Activity A22, and the processor 43 searches for the maximum output power Pmax corresponding to the thermoelectromotive force E based on the predetermined reference information IFO. The details of the process are the same as those of Activity A12. Thereafter, the determination unit 433 compares the obtained required power P with the maximum output power Pmax obtained by the search and determines their magnitude relationship.

### [Activity A23]

In the case where the required power P is equal to or less than the maximum output power Pmax, the process proceeds to Activity A23, and the device control unit 436 causes the power storage device 2 to output electric power in response to the required power P of the drive device M1. The details of the process are the same as those of Activity A13. Then, the process proceeds to Activity A25.

### [Activity A24]

On the other hand, in the case where the required power P is greater than the maximum output power Pmax, the process proceeds to Activity A24, and the device control unit 436 limits the drive device M1 so that the required power P of the drive device M1 becomes equal to or less than the maximum output power Pmax. Then, the device control unit 436 causes the power storage device 2 to output power in response to the limited required power P. The details of the process are the same as those of Activity A14. Then, the process proceeds to Activity A25.

### [Activity A25]

In Activity A25, the acquisition unit 431 acquires the output power of the power storage device 2 and stores the history of the output power in the storage unit 42 or the like. The output power of the power storage device 2 is an example of information related to the second electrical signal output from the power storage device 2, and may be output voltage, output current, etc. The process then returns to Activity A21.

### [Activity A26]

Meanwhile, after Activity A25, the estimation unit 435 estimates a state of charge (SOC) or a state of health (SOH) of the power storage device 2 based on the output history of the output power of the power storage device 2 and the thermoelectromotive force E, and updates the existing SOC and SOH to the estimated values in Activity A26. According to such a configuration, the operation of the power storage device 2 can be made more stable. Any method may be used to estimate the state of the power storage device 2, but for example, the estimation unit 435 estimates the temperature and temperature change of the power storage device 2 based on the thermoelectromotive force E. Next, the estimation unit 435 compares the estimated temperature change and the output history of the output power to estimate the power consumption inside the power storage device 2 due to discharge, etc. of the power storage device 2 at that temperature. Next, the estimation unit 435 estimates the internal resistance of the power storage device 2 based on the power consumption inside the power storage device 2 and the output voltage of the power storage device 2. The internal resistance is one of the indices representing the SOH of the power storage device 2. By correcting such internal resistance with temperature, the estimation unit 435 can estimate the SOH that reflects the temperature of the power storage device 2. Similarly, the estimation unit 435 can estimate the current SOC of the power storage device 2 taking into account the temperature state of the power storage device 2, by integrating the power output to the drive device M1 and the power consumed inside the power storage device 2 and performing a calculation such as subtracting the integrated power from the power capacity in the fully charged state.

### [Activity A27, Activity A28]

Furthermore, when the third information processing is being executed, the detection unit 432 may detect that the thermoelectromotive force E has exceeded the threshold voltage Vt1, in activity A27. In this case, the process exceptionally proceeds to Activity A28, and the detection unit 432 detects, based on the thermoelectromotive force E, abnormal operation of the power storage device 2 accompanied by heat generation.

### [Activity A29]

The process then proceeds to Activity A29, and the processor 43 turns off the switch 36 corresponding to the power storage device 2 in which the abnormal operation has been detected. The details of the process are the same as those of Activity A4.

### [Activity A30]

The process then proceeds to Activity A30, and the display processing unit 437 notifies the user of the detection result of the abnormal operation. The details of the process are the same as those of Activity A5. Then, the third information processing ends.

The above information processing may be executed individually or in combination. Additionally, the above information processing may be executed independently, in parallel, or in a coordinated manner.

### 5. Configuration Example of Information Processing System 1 for Estimating Position Information, Etc. Of Heat Generation Position of Power Storage Device 2

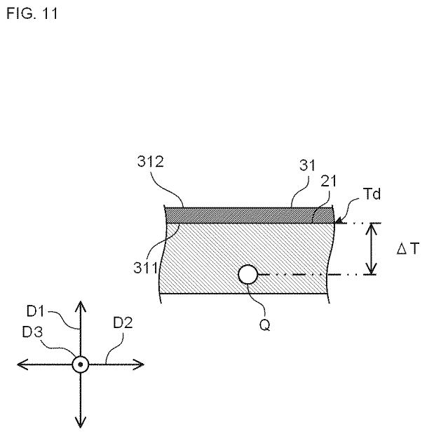

This section describes a configuration example of the information processing system 1 for estimating position information, etc. of the heat generation position of the power storage device 2. For convenience of explanation, the power storage unit BU is configured so that the thermoelectric conversion part 31 comes into contact with the first region 311 not through the first heat conduction portion 33. However, as described above, the same applies to the case in which the thermoelectric conversion part 31 comes into contact with the housing 21 through the first heat conduction portion 33. FIG. 11 is a cross-sectional view of the power storage device 2 and the thermoelectric conversion part 31 that comes into contact with the power storage device 2, in a plane perpendicular to the third direction D3.

As shown in FIG. 11, the heat source Q may be located at a position away from the surface of the housing 21 in the first direction D1. Thus, the temperature of the heat source Q deviates from the surface temperature of the housing 21 (in other words, the temperature of the first region 311) by a temperature difference ΔT. Thus, the surface temperature of the housing 21 which is estimated from the temperature gradient J, deviates by the temperature difference ΔT.

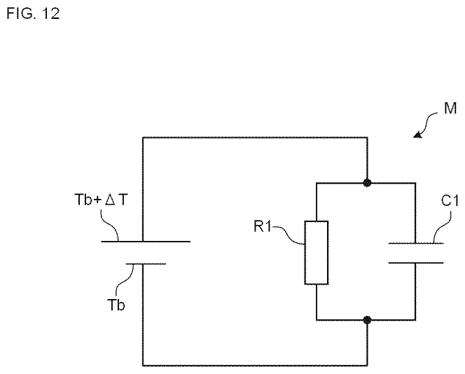

In contrast, the estimation unit 435 of the present embodiment sets the temperature of the first region 311 as a detected temperature Td and constructs a thermal circuit model M for the heat conduction path from the first region 311 to the heat source Q by simulation or the like. FIG. 12 shows an example of a thermal circuit model M. The estimation unit 435 may use the thermal circuit model M to estimate various information, such as the depth temperature of the heat source Q from the thermoelectromotive force E, and its positional information (e.g., the distance in the first direction D1 from the surface of the housing 21 to the heat source Q). The thermal circuit model M is represented as, for example, a parallel connection of a heat resistance R1 and a thermal capacity C1, and the estimation unit 435 estimates these parameters by simulation or the like. The relationship between the temperature difference ΔT, heat resistance, and heat capacity C1 is expressed, for example, by the following equation. Here, Q represents the amount of heat generation of the heat source Q, and n is a natural number representing the number of steps that represent the temporal change in the amount of heat generation of the heat source Q.

$$Δ T [ n ] = \frac{1}{1 + α} \times Δ T [ n - 1 ] + k \times Q [ n ] \qquad [ Equation 1 ]$$

However, α=t_sampling/(R1×C1) and k=t_sampling/C1. The t_samplng indicates the time of the sampling period.

To summarize the above, the estimation unit 435 is configured to estimate position information of a heat generation position of the power storage device 2 relative to the surface of the power storage device 2 based on a predetermined thermal conduction model of the power storage device 2 and the temperature of the surface of the power storage device 2 based on the thermoelectromotive force E. According to such a configuration, the position of a heat source present inside the power storage device 2 can be easily grasped.

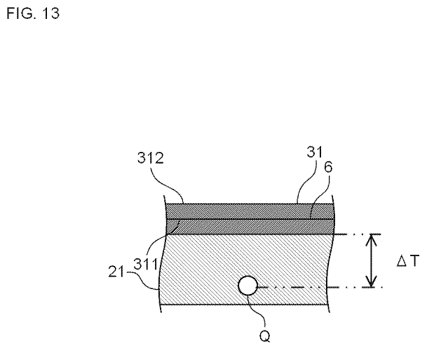

When correcting temperature changes or the like, the information processing system 1 may further include a temperature adjusting element 6. FIG. 13 is a cross-sectional view of the power storage device 2, etc., taken along a plane perpendicular to the third direction D3 in a case where the thermoelectric conversion part 31 comes into contact with the power storage device 2 through the temperature adjusting element 6. The temperature adjusting element 6 is configured to adjust the temperature of the first region 311 of the thermoelectric conversion part 31 based on the control of the information processing apparatus 4 or the like, and is implemented using, for example, a sheet heater or a Peltier element. The temperature adjusting element 6 is arranged between the housing 21 and the first region 311 of the thermoelectric conversion part 31. It is preferable that the temperature adjusting element 6 includes a conduction path for the heat flow from the housing 21 to the first region 311. The information processing apparatus 4 controls the temperature adjusting element 6 based on the thermoelectromotive force E accompanied by the temperature gradient J and drives the temperature adjusting element 6 so that the thermoelectromotive force E decreases. As a result, the temperature adjusting element 6 adjusts the temperature of the first region 311 so that the temperature gradient J between the first region 311 and the second region 312 is less than a predetermined value. In this manner, a compact control system can be constructed by performing closed-loop control using the thermoelectric conversion part 31, the information processing apparatus 4, and the temperature adjusting element 6. In addition, the estimation unit 435 may estimate various information such as internal parameters of the above thermal circuit model M (e.g., heat resistance R1, heat capacity C1, etc.), position information of the heat source Q, and the degree of deterioration of the power storage device 2, from the control values such as the temperature of the temperature adjusting element 6 at that time, the heat flow (temperature gradient J), the temperature response, or the like.

### 6. Another Example of Signal Processing Circuit 35

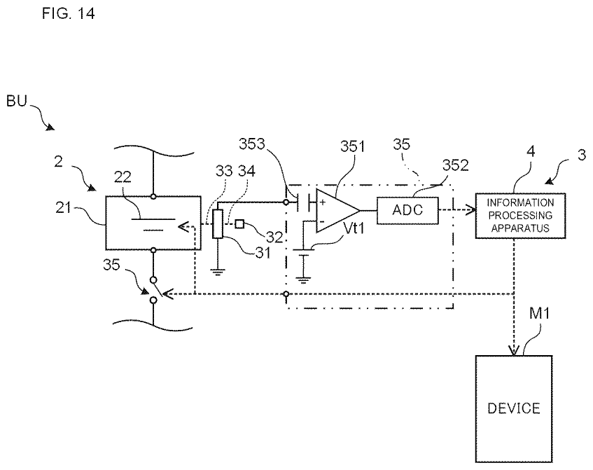

This section describes another example of the signal processing circuit 35 described above. FIG. 14 shows another example of the signal processing circuit 35. As shown in FIG. 14, the signal processing circuit 35 may further include a capacitor 353. The capacitor 353 is arranged between the thermoelectric conversion part 31 and a non-inverting input terminal of the comparing unit 351. The capacitor 353 converts the first electrical signal that is input to the comparing unit 351 to a signal corresponding to the time differentiation from a thermoelectromotive force E to the thermoelectromotive force E, i.e., the rate of change of the temperature gradient J per unit time. In this case, the information processing apparatus 4 can perform the above-mentioned control based on the signal corresponding to the time differentiation of such a thermoelectromotive force E. This signal is particularly suitable for detecting a tendency to generate heat rapidly due to leakage of the electrolyte of the power storage portion 22, etc.

The function of the signal processing circuit 35 may be realized by the information processing apparatus 4. That is, the information processing apparatus 4 may function as a signal processing unit. In other words, the above-mentioned signal processing circuit 35 is not limited to those implemented by an analog circuit, but may be realized by the processor 43 of the information processing apparatus 4 executing a predetermined program. The specific configuration of the signal processing circuit 35 is arbitrary and is not limited to those described above.

### [Others]

The above-mentioned aspect of the information processing system 1 is merely an example, and the present disclosure is not limited thereto.

In Activity A2 of each of the above information processing, the detection unit 432 detects abnormal operation of the power storage device 2 accompanied by heat generation, based on the comparison result between the thermoelectromotive force E and the threshold voltage Vt1. However, the aspect of detecting abnormal operation is not limited to this and is arbitrary. For example, the detection unit 432 may detect abnormal operation of the power storage device 2 based on whether or not the acquired information on the thermoelectromotive force E satisfies a pre-specified condition indicating abnormal operation. Such a condition may be specified based on test results, simulation results, and the like. The method for specifying the condition is arbitrary, and the condition may be specified by processing the test results, etc. using any statistical method, or by using a trained model that is trained by inputting the test results or the like. The learning algorithm of the trained model is arbitrary, for example, examples thereof include supervised learning, semi-supervised learning, unsupervised learning, and reinforcement learning. The information related to the thermoelectromotive force E is not limited to the thermoelectromotive force E itself, but may include various aspects such as differential values, integral values, and time-series information of the thermoelectromotive force E. In particular, the detection unit 432 may detect abnormal operation of the power storage device 2 based on time-series information of the thermoelectromotive force E. This makes it possible to detect abnormal operation while taking the influence of continuous usage of devices such as the power storage device 2 into consideration, thereby improving convenience.

As in the case of Activity A2, the changing unit 434 may change the operation of the power storage device 2 in Activity A12 or the like, based on something other than the result of comparing the thermoelectromotive force E with various reference values such as the maximum output power Pmax. The changing unit 434 may change the operation of the power storage device 2 based on whether or not the thermoelectromotive force E is included in a range of the thermoelectromotive force E corresponding to the changed operation. In particular, the changing unit 434 may change the operation of the power storage device 2 based on the time-series information of the thermoelectromotive force E. This makes it possible to change the operation of the device such as the power storage device 2, for example, while taking the influence of continuous usage of devices such as the power storage device 2 into consideration, thereby reducing the burden on the devices, etc.

The temperature adjustment part 31 is not limited to the heat bath 32, but may be a heat sink, a water cooling device, or the like, and may be any component as long as it can adjust the temperature of the second heat conduction portion 34 or the second region 312 of the thermoelectric conversion part 31. According to such a configuration including the temperature adjustment part, the change in the temperature gradient J due to heat generation of the power storage device 2 changes in a short time compared to the temperature change due to heat generation of the power storage device 2. As a result, the abnormal heat generation of the power storage device 2 can be detected with higher sensitivity compared with the conventional manner.

The first signal is not limited to the thermoelectromotive force E, but may be an electrical signal such as current or power resulting from the thermoelectromotive force E, or a magnetic force induced by the current.

The second signal is not limited to voltage, current, and power, and may be any signal including information that enables the SOC or SOH of the power storage portion 22 of each power storage device 2 to be estimated.

The main surface portion 331 does not have to be arranged along the outer edge of the housing 21, and the shape of the main surface portion 331 is arbitrary as long as it can transfer heat from the heat source Q to the thermoelectric conversion part 31. For example, the main surface portion 331 may be formed so that the outer edge of the main surface portion 331 contains an area in which the power storage portion 22 may be present when the housing 21 is viewed in a plan view from the first direction D1.

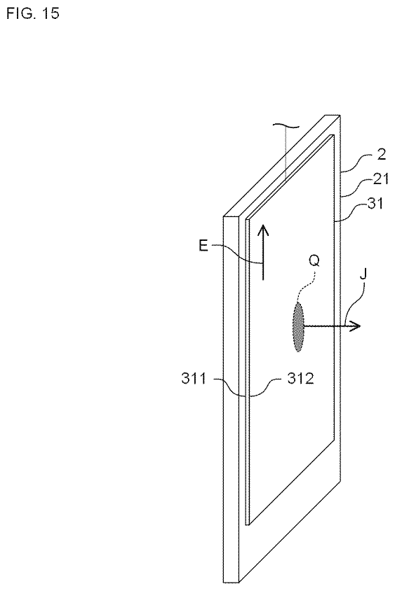

The signal processing system 3 may not include the first heat conduction portion 33. FIG. 15 shows an example of the signal processing system 3 that does not include the first heat conduction portion 33. As shown in FIG. 15, the thermoelectric conversion part 31 is arranged so that the first region 311 comes into direct contact with the housing 21 not through the first heat conduction portion 33. At this time, the shape of the thermoelectric conversion part 31 is similar to that of the main surface portion 331 of the first heat conduction portion 33 described above. That is, the thermoelectric conversion part 31 is formed so that the outer edge of the housing 21 contains the outer edge of the thermoelectric conversion part 31 when viewed in a plan view from the first direction D1. This makes it possible to detect that the heat source Q is generated over a wider area.

The first heat conduction portion 33 may not include the main surface portion 331 but may include the protruding portion 332. In this case, the protruding portion 332 is arranged so as to come into contact with at least a portion of the outer edge of the housing 21.

The signal processing system 3 may not include the second heat conduction portion 34. For example, the thermoelectric conversion part 31 may be configured so that the second region 312 comes into direct contact with the heat bath 32 not through the second heat conduction portion 34. For example, the heat bath 32 only needs to be arranged so as to cover the second region 312 of the thermoelectric conversion part 31 from the first direction D1. The signal processing system 3 may not include the heat bath 32.

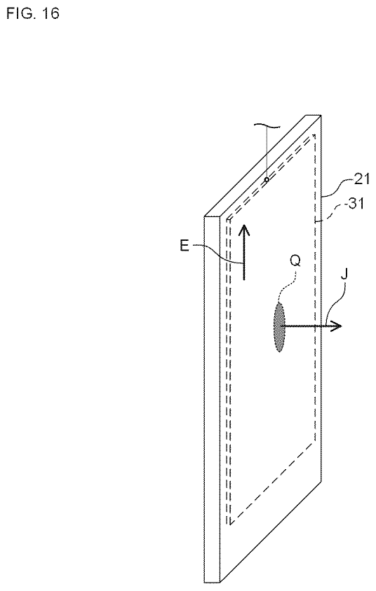

The position where the thermoelectric conversion part 31 is mounted may be any position as long as it is possible to detect the presence of the heat source Q, and the position is not limited to the surface of the housing 21. FIG. 16 shows an example of a mounting aspect of the thermoelectric conversion part 31. As shown in FIG. 16, the thermoelectric conversion part 31 may be housed inside the housing 21. In this case, the shape of the thermoelectric conversion part 31 is arbitrary, and may be, for example, a flat plate shape as shown in FIG. 15.

The thermoelectric conversion part 31 is not limited to one that exhibits the anomalous Nernst effect as described above, and may be configured to exhibit the Seebeck effect or the like. In this case, since the temperature gradient J induces a thermoelectromotive force E that includes a component parallel to the temperature gradient J, the thermoelectric conversion part 31 needs to be wired so as to extract the thermoelectromotive force E in a direction parallel to the temperature gradient J.

The object to be connected to the power storage unit BU is not limited to those that are driven by electric power from the power storage unit BU, such as the drive device M1 described above. For example, the power storage unit BU may be connected to a charging device that supplies power to the power storage unit BU. The charging device includes, for example, a power source such as a commercial power source, and a power converter that converts power from the power source. In this case, the information processing apparatus 4 of the power storage unit BU transmits the required power P to the charging device, and the power storage unit BU transmits power corresponding to the required power P to the power storage unit BU. The information processing described above can also be applied to the information processing system 1 configured in this way.

In the above embodiment, the case where the power storage device 2 generates heat from the heat source Q has been described. However, the same applies to the case where the power storage device 2 absorbs heat from the heat source Q. That is, the same applies to the case where the temperature of the first region 311 of the thermoelectric conversion part 31 is lower than the temperature of the second region 312 due to circumstances such as the temperature of the housing 21 being lower than the temperature of the heat bath 32, or the like. Thus, the heat exchange between the power storage device 2 and the thermoelectric conversion part 31 is not limited to the case where heat is transferred from the power storage device 2 to the thermoelectric conversion part 31, but may also include the case where heat is transferred from the thermoelectric conversion part 31 to the power storage device 2.

The information processing executed in the information processing system 1 may be on-premises or in the cloud. The in-cloud external device may provide the above-described functions and processing in the form of, for example, SaaS (Software as a Service) or cloud computing.

In the above-described embodiment, the signal processing system 3 and the information processing apparatus 4 execute various storage and control operations, but a plurality of external devices may be used instead of the signal processing system 3 and the information processing apparatus 4. In other words, various information and programs may be divided to be stored into the plurality of the external devices by using blockchain technology or the like.

The above-mentioned embodiment is not limited to the information processing system 1, and may be an information processing method or an information processing program.

Thus, to summarize the above, the information processing method executed by the information processing system 1 includes the following steps. In a thermoelectric conversion step, a thermoelectromotive force E is generated in response to the temperature gradient J generated in the thermoelectric conversion part 31 by heat exchange with the power storage device 2 as a device. The power storage device 2 as a device is configured to generate heat depending on the operating state of the device. The determination unit 433 determines the operating state of the device in response to the thermoelectromotive force E.

To summarize the above, the information processing method executed by the information processing system 1 includes the following steps. The thermoelectric conversion step is configured to generate a temperature gradient J by heat exchange with the power storage device 2, and to generate a thermoelectromotive force E based on the temperature gradient J. In an acquisition step, the thermoelectromotive force E is acquired. In a detection step, abnormal operation of the power storage device 2 accompanied by heat generation is detected based on the thermoelectromotive force E.

According to such a configuration, the change in the temperature gradient J due to heat generation of the power storage device 2 changes in a short time compared to the temperature change due to heat generation of the power storage device 2. As a result, the abnormal heat generation of the power storage device 2 can be detected with higher sensitivity compared with the conventional manner.

In addition, the present disclosure may be provided with each of the following aspects.

(1) An information processing system, comprising: a thermoelectric conversion part configured to generate a temperature gradient by heat exchange with a device and to generate a thermoelectromotive force based on the temperature gradient; and a signal processing unit including: an acquisition unit configured to acquire the thermoelectromotive force; and a detection unit configured to detect, based on the thermoelectromotive force, abnormal operation of the device accompanied by heat generation.

According to such a configuration, the change in the temperature gradient due to heat generation of the device changes in a short time compared to the temperature change due to heat generation of the device. As a result, the abnormal heat generation of the device can be detected with higher sensitivity compared with the conventional manner.

(2) An information processing system, comprising: a thermoelectric conversion part configured to generate a thermoelectromotive force in response to a temperature gradient generated in the thermoelectric conversion part by heat exchange with a device; and a signal processing unit including: an acquisition unit configured to acquire the thermoelectromotive force; and a device control unit configured to control operation of the device based on the acquired thermoelectromotive force.

According to such a configuration, the change in the temperature gradient due to heat generation of the device changes in a short time compared to the temperature change due to heat generation of the device. As a result, the device can be controlled with a faster response speed compared with the conventional manner.

(3) The information processing system according to (1) or (2), wherein the thermoelectric conversion part is configured to generate the thermoelectromotive force including a component generated in a direction different from the temperature gradient.

According to such a configuration, it becomes easier to measure the thermoelectromotive force from a direction different from the temperature gradient, thereby reducing the wiring, etc. between the device and the thermoelectric conversion part. Thus, the decrease in sensitivity to the temperature gradient can be suppressed.

(4) The information processing system according to any one of (1) to (3), further comprising: a first heat conduction portion configured to connect the device and the thermoelectric conversion part.

According to such a configuration, heat exchange between the device and the thermoelectric conversion part is conducted through the first heat conduction portion, thus making it easier to reduce variations in the thermoelectromotive force caused by differences in the heat generation positions of the device.

(5) The information processing system according to (4), wherein the first heat conduction portion includes a protruding portion, the protruding portion is configured to protrude from the device when the device is viewed in a plan view from a predetermined first direction, and the thermoelectric conversion part is connected to the protruding portion.

According to such a configuration, the thermoelectromotive force of the thermoelectric conversion part can be measured more easily, and thus the degree of freedom in arranging the device and the like can be improved.

(6) The information processing system according to any one of (1) to (5), further comprising: a second heat conduction portion, wherein the thermoelectric conversion part includes a first region in which heat exchange with the device is performed and a second region positioned in a direction of the temperature gradient from the first region, and the second heat conduction portion is connected to the second region.

According to such a configuration, it is possible to grasp the temperature gradient that occurs in the thermoelectric conversion unit depending on the temperature of the second heat conduction portion. This can increase the information obtained from the thermoelectromotive force. Thus, a wider variety of heat-related processing can be performed.

(7) The information processing system according to (6), wherein the second heat conduction portion is connected to a temperature adjusting part configured to adjust temperature of the second heat conduction portion.

According to such a configuration, it becomes easier to more accurately grasp the temperature gradient of the thermoelectric conversion part.

(8) The information processing system according to (6) or (7), wherein the second heat conduction portion includes a heat dissipation portion configured to dissipate at least a portion of heat flowing into the thermoelectric conversion part through the heat exchange.

According to such a configuration, heat generated by heat generation of the device can be released from the heat dissipation portion, so that an excessive increase in temperature of the thermoelectric conversion part can be suppressed.

(9) The information processing system according to any one of (6) to (8), wherein the second heat conduction portion is configured to be connected to a heat bath having a predetermined reference temperature, thereby maintaining temperature of the second region at approximately the reference temperature.

According to such a configuration, the operating temperature of the thermoelectric conversion part is stabilized, thereby improving the detection accuracy of the heat generation state of the device.

(10) The information processing system according to (9), wherein the signal processing unit further including: a comparing unit configured to compare a first signal due to the thermoelectromotive force of the thermoelectric conversion part with a predetermined reference value; and a changing unit configured to change operation of the device based on a comparison result of the first signal.

According to such a configuration, the thermoelectromotive force generated from the thermoelectric conversion part can be grasped as a difference from the reference value. Thus, it becomes easier to stably change the operation of the device by the electric signal output from the thermoelectric conversion part.

(11) The information processing system according to any one of (1) to (10), wherein the device is a power storage device configured to charge and discharge power, the signal processing unit further includes a first estimation unit, the acquisition unit is configured to acquire information related to a second signal output from the power storage device, and the first estimation unit is configured to estimates a state of charge or a state of health of the power storage device based on an output history of the second signal and the thermoelectromotive force.

According to such a configuration, the operation of the power storage device can be made more stable.

(12) The information processing system according to any one of (1) to (11), wherein the thermoelectric conversion part is configured so that the thermoelectromotive force changes in response to a temperature change of a surface of the device due to heat generation, the signal processing unit further includes a second estimation unit configured to estimate position information of a heat generation position of the device relative to a surface of the device based on a predetermined thermal conduction model of the device and temperature of the surface of the device based on the thermoelectromotive force.

According to such a configuration, the position of a heat source present inside the device can be easily grasped.

(13) The information processing system according to any one of (1) to (12), further comprising the device.

According to such a configuration, the change in the temperature gradient due to heat generation of the device changes in a short time compared to the temperature change due to heat generation of the device. As a result, the abnormal heat generation of the device can be detected with higher sensitivity compared with the conventional manner.

(14) An information processing method, comprising: a thermoelectric conversion step of generating a thermoelectromotive force in response to a temperature gradient generated in a thermoelectric conversion part by heat exchange with a device that is configured to generate heat depending on an operating state of the device; and a determination step of determining an operating state of the device in response to the thermoelectromotive force.

According to such a configuration, the change in the temperature gradient due to heat generation of the device changes in a short time compared to the temperature change due to heat generation of the device. As a result, the operating state of the device can be determined with higher sensitivity compared with the conventional manner.

(15) An information processing method, comprising: a thermoelectric conversion step of generating a temperature gradient by heat exchange with a device and generating a thermoelectromotive force based on the temperature gradient; an acquisition step of acquiring the thermoelectromotive force; and a detection step of detecting, based on the thermoelectromotive force, abnormal operation of the device accompanied by heat generation.

According to such a configuration, the change in the temperature gradient due to heat generation of the device changes in a short time compared to the temperature change due to heat generation of the device. As a result, the abnormal heat generation of the device can be detected with higher sensitivity compared with the conventional manner.

Of course, the present disclosure is not limited to the above aspects.

Finally, various embodiments of the present disclosure have been described, but these are presented as examples and are not intended to limit the scope of the invention. Novel embodiments can be implemented in various other forms, and various omissions, replacements, and modifications can be made within the scope of the spirit of the invention. The embodiments and its modifications are included in the scope and the spirit of the invention and are included in the scope of the invention described in claims and the equivalent scope thereof.

In addition, the following points should also be noted.

Conventionally, efforts have been made to ensure the safety of a system based on the temperature of a single point. Currently, abnormal heat generation in the battery is detected using a temperature sensor. For this reason, it is only possible to detect an abnormal state in which the temperature has risen. In addition, since only a local temperature rise is detected, it may not be noticed until the temperature becomes significantly high. Currently, abnormal heat generation is measured by temperature, so the abnormality cannot be detected until the battery warms up. Only a local temperature can be detected.

By using a thin-film heat flow sensor that can measure the amount of heat generation, it is possible to stop the discharging and charging of the battery before an abnormal state progresses. In addition, range measurement is possible using surfaces and electric heating paths, and thus the system can be configured in such a manner that is less likely to miss abnormal areas. As the amount of heat generation can be measured directly, faster measurements are possible, and abnormal heat generation can be detected comprehensively.

This embodiment will be described below. In this embodiment, by attaching a heat flow sensor to the battery pack to monitor the amount of heat generation, abnormal detection can be performed more quickly than with temperature measurements. In addition, mounting the sensor over a larger area enables an abnormality to be detected over a larger area.

From the viewpoint of responsiveness, the heat flow sensor of this embodiment is preferably a thin-film type heat flow sensor based on the anomalous Nernst effect. The element of the heat flow sensor (i.e., thermoelectric conversion device) may be composed of a compound that exhibits the anomalous Nernst effect. The element may be composed of, for example, topological ferromagnetic materials or topological antiferromagnetic materials, called Weyl semimetals, or it may be composed of ferrimagnetic materials, or it may be a combination of these. The topological ferromagnetic material may be a metal with a Co₂TX composition, such as Co₂MnGa (where X is any one of Si, Ge, Sn, Al, and Ga), or an alloy of a known topological ferromagnetic material, such as a metal with a composition formula represented by Fe₃X (where X is a stoichiometric composition that is a typical element or transition element such as Al or Ga). The topological antiferromagnetic material may be a known topological antiferromagnetic material such as Mn₃X (where X is one or more elements selected from Sn, Ge, Ga, Pt, Ir, Rh, or a compound thereof). The compound constituting the element may be, for example, an alloy containing a transition metal, and the alloy may be a compound having a crystal structure with kagome lattice planes formed by the transition metal, and may exhibit the anomalous Nernst effect. The ferrimagnetic materials are also not particularly limited, as long as they exhibit the anomalous Nernst effect. The structure of the element is not particularly limited, and any known structures can be used.

Furthermore, a heat flow sensor may be provided directly on the battery pack. Since the sensor is a thin-film heat flow sensor, a substrate such as a PCB for the sensor is not required. The heat flow sensor may be installed on each cell, or in the case of multi-cell configuration, it may be installed on each cell.

A heat sink may be provided on the heat flow sensor. The heat sink may be of a known type, but its structure needs to be designed appropriately. Since the heat flow sensor can be adjusted by using a heat sink, the thermal design may include a heat sink. The heat sink only needs to ensure the heat flow path, and it is therefore obvious that the optimal shape may be used for each design. Furthermore, not limited to the use of heat sinks, it is even better to use cooling means such as air or water cooling to manage the thermal state, and it is therefore obvious that the performance can be further improved by using a temperature sensor to manage the temperature of the heat flow sensor. It is therefore obvious that this cell may be a multi-cell.

The heat flow sensor may be provided inside the battery cell. Since the sensor is a thin-film heat flow sensor, it is possible to detect heat generation even if it is placed inside the battery cell as long as the terminal can be brought outside. In that case, the location of installation is not a problem as long as it is a chemically stable area, such as between the case and the inside of the battery, or between the electrodes. In that case, using electrodes, a case, or the like as a heat sink is also acceptable. It is also acceptable for the cell to be configured as a multi-cell arrangement.

In addition, a heat conducting path for conducting heat may be provided. A heat conduction path is formed for the heat flow sensor to conduct heat and detect the heat flow. This makes it possible to detect even in places where it is difficult to insert a sensor. Furthermore, while the heat conducting path and the heat flow sensor are electrically insulated, it is preferable to use fine ceramics, semiconductors, resins, paste materials, or the like that allow heat to pass through. Even if the heat flow sensor comes into electrical contact with the heat conduction path, noise may increase, but the measurement is still possible. The heat conducting path may be made of existing materials, such as Al electrodes of a battery material.

An example of a battery fail-safe system based on the heat flow detection system of this embodiment is shown below. The absolute value or slope of the amount of heat generation Q, or a value derived from the amount of heat generation, or a calculated value using the amount of heat generation and other parameters can be used as a determination value to cut off charging/discharging of the battery. Mounting such a fail-safe function allows for more reliable battery management. The following equations are described using analog circuits, but digital control is also acceptable. The above information can also be used to provide feedback for the control of the charging/discharging of the battery, allowing for more reliable battery management.

For multiple batteries, those detected to have large heat generation during battery charging or discharging temporarily stop charging or discharging, and switching is performed with DUTY that minimizes heat flow, thereby extracting the required power from the multiple batteries. Other methods may also be used as long as balancing is possible.

Conventionally, the State of Health (SOH) of a battery has been estimated based on information on the battery's internal impedance, current, voltage, the number of charge/discharge cycles, and temperature history. However, the accuracy of the SOH can be further improved by incorporating the amount of heat generation. For example, it is possible to detect battery degradation by monitoring the amount of heat generation under the same voltage and current driving conditions. In addition, by comparing unit energy or similar parameters, it is possible to make a real-time comparison of SOH. It is therefore obvious that this can also be used to estimate other characteristic parameters of the battery. This data can also be used to calculate battery life and recommend replacement.

In another embodiment, the deep internal temperature of the battery can be measured from the amount of heat generation of the battery. This measurement information may be used in the system. The model is a simplified model, but an estimation model can be created to suit the system.

Furthermore, a heating element may be provided between the sensor and the battery to perform closed control and perform model-based prediction and measurement. Furthermore, internal parameters can be estimated from the control value, heat flow, temperature response, etc., R1 and C1 can be estimated, and the distance to the heat source can also be estimated, thus making it possible to detect the impact of deterioration, etc., in more detail. Since it becomes possible to obtain information on R1 and C1, measurements that are resistant to disturbances (individual differences and changes over time) can be performed.

1. An information processing system, comprising:
a thermoelectric conversion part configured to generate a temperature gradient by heat exchange with a device and to generate a thermoelectromotive force based on the temperature gradient; and
a signal processing unit implemented by circuitry, including:
an acquisition unit implemented by circuitry configured to acquire the thermoelectromotive force; and
a detection unit implemented by circuitry configured to detect, based on the thermoelectromotive force, abnormal operation of the device accompanied by heat generation.

2. An information processing system, comprising:
a thermoelectric conversion part configured to generate a thermoelectromotive force in response to a temperature gradient generated in the thermoelectric conversion part by heat exchange with a device; and
a signal processing unit implemented by circuitry, including:
an acquisition unit implemented by circuitry configured to acquire the thermoelectromotive force; and
a device control unit implemented by circuitry configured to control operation of the device based on the acquired thermoelectromotive force.

3. The information processing system according to claim 1, wherein
the thermoelectric conversion part is configured to generate the thermoelectromotive force including a component generated in a direction different from the temperature gradient.

4. The information processing system according to claim 1, further comprising:
a first heat conduction portion configured to connect the device and the thermoelectric conversion part.

5. The information processing system according to claim 4, wherein
the first heat conduction portion includes a protruding portion,
the protruding portion is configured to protrude from the device when the device is viewed in a plan view from a predetermined first direction, and
the thermoelectric conversion part is connected to the protruding portion.

6. The information processing system according to claim 1, further comprising:
a second heat conduction portion, wherein
the thermoelectric conversion part includes a first region in which heat exchange with the device is performed and a second region positioned in a direction of the temperature gradient from the first region, and
the second heat conduction portion is connected to the second region.

7. The information processing system according to claim 6, wherein
the second heat conduction portion is connected to a temperature adjusting part configured to adjust temperature of the second heat conduction portion.

8. The information processing system according to claim 6, wherein
the second heat conduction portion includes a heat dissipation portion configured to dissipate at least a portion of heat flowing into the thermoelectric conversion part through the heat exchange.

9. The information processing system according to claim 6, wherein
the second heat conduction portion is configured to be connected to a heat bath having a predetermined reference temperature, thereby maintaining temperature of the second region at approximately the reference temperature.

10. The information processing system according to claim 9, wherein
the signal processing unit further including:
a comparing unit implemented by circuitry configured to compare a first signal due to the thermoelectromotive force of the thermoelectric conversion part with a predetermined reference value; and
a changing unit implemented by circuitry configured to change operation of the device based on a comparison result of the first signal.

11. The information processing system according to claim 1, wherein
the device is a power storage device configured to charge and discharge power,
the signal processing unit further includes a first estimation unit implemented by circuitry,
the acquisition unit is configured to acquire information related to a second signal output from the power storage device, and
the first estimation unit is configured to estimates a state of charge or a state of health of the power storage device based on an output history of the second signal and the thermoelectromotive force.

12. The information processing system according to claim 1, wherein
the thermoelectric conversion part is configured so that the thermoelectromotive force changes in response to a temperature change of a surface of the device due to heat generation,
the signal processing unit further includes a second estimation unit implemented by circuitry configured to estimate position information of a heat generation position of the device relative to a surface of the device based on a predetermined thermal conduction model of the device and temperature of the surface of the device based on the thermoelectromotive force.

13. The information processing system according to claim 1, further comprising the device.

14. An information processing method, comprising:
a thermoelectric conversion step of generating a thermoelectromotive force in response to a temperature gradient generated in a thermoelectric conversion part by heat exchange with a device that is configured to generate heat depending on an operating state of the device; and
a determination step of determining an operating state of the device in response to the thermoelectromotive force.

15. (canceled)

16. The information processing system according to claim 2, further comprising the device.
